(19) United States
(12) Patent Application Publication
(10) Pub. No.: US 2025/0246440 A1
(43) Pub. Date: Jul. 31, 2025

(54) METHOD FOR MEASURING RESISTIVITY OF SILICON SINGLE CRYSTAL

(71) Applicant: SHIN-ETSU HANDOTAI CO., LTD., Tokyo (JP)

(72) Inventors: Keisuke MIHARA, Nishigo-mura (JP); Shigeru YAZAWA, Nishigo-mura (JP); Masaaki OSEKI, Nishigo-mura (JP); Yuki TANAKA, Nishigo-mura (JP)

(73) Assignee: SHIN-ETSU HANDOTAI CO., LTD., Tokyo (JP)

(21) Appl. No.: 19/016,148

(22) Filed: Jan. 10, 2025

(30) Foreign Application Priority Data
Jan. 29, 2024 (JP) 2024-010783

(51) Int. Cl. H01L 21/324; G01R 27/02; H01L 21/304; H01L 21/306

(52) U.S. Cl. CPC H01L 21/3247; G01R 27/02; H01L 21/304; H01L 21/30604

(57) ABSTRACT

The present invention is a method for measuring resistivity of a silicon single crystal with resistivity of 100 Ωcm or higher, the silicon single crystal being grown with addition of nitrogen by an MCZ method, the method including: performing oxidation heat treatment at a temperature of 1100 to 1250° C. for 90 to 240 minutes on a substrate sliced from the silicon single crystal to form a thermal oxide film on a surface of the substrate; and measuring resistivity of the substrate after removing the thermal oxide film from the surface of the substrate. This provides a method for measuring resistivity of a silicon single crystal is provided which can measure a precise resistivity derived from a dopant for a silicon single crystal with resistivity of 100 Ωcm or higher that is grown with addition of nitrogen by the MCZ method.

### TECHNICAL FIELD

The present invention relates to a method for measuring the resistivity of a silicon single crystal with resistivity of 100 Ωcm or higher that is grown with addition of nitrogen by a magnetic field applied Czochralski (MCZ) method.

### BACKGROUND ART

RF (high frequency) devices are used for communication applications such as smartphones. Compound semiconductors have mostly been used for the RF devices. However, in recent years, RF devices based on silicon single crystals have widely been used because of even finer CMOS processes, a demand for lower costs in device fabrication, or other reasons.

In the RF devices using silicon single crystal wafers, with a lower substrate resistivity, that is, a higher dopant concentration, conductivity is high and loss is increased. Thus, there is a demand for substrates with high resistivity, specifically, 100 Ωcm or higher. Wafers called silicon on insulator (SOI) are often used, in which a thin oxide film and a thin silicon layer are formed on a surface layer portion of a silicon substrate. High resistivity is also desired in this case. There is also a demand for substrates with high resistivity in high withstand voltage applications for power devices.

In RF (high frequency) devices and power devices, the presence of oxygen donors in silicon substrates deteriorates their characteristics, so there is a demand for silicon single crystals with low oxygen concentration in order to suppress oxygen donors.

In a Czochralski (CZ) method, a silicon raw material melt is accommodated in a quartz crucible. Oxygen is eluted into the raw material melt from the quartz crucible during crystal pulling-up, and oxygen incorporated into single crystal.

As a method for obtaining a low-oxygen crystal, for example, Patent Document 1 discloses a method for obtaining a low-oxygen crystal by defining a crystal rotation rate and a crucible rotation rate under a horizontal magnetic field. Patent Document 2 discloses a method with a magnetic field intensity of a horizontal magnetic field of 2000 G or more, a quartz crucible rotation rate of 0.2 rpm or less, and a crystal rotation rate of 5 rpm or less. Patent Document 3 discloses a method for obtaining a low-oxygen crystal by defining a magnetic field minimum plane position, a melt surface position, and an intensity of magnetic field at an intersection of an intermediate plane between upper and lower coils and an inner wall of a quartz crucible, under a cusp magnetic field.

In this way, in the recent fabrication of silicon single crystals by the CZ method, low-oxygen crystals can be stably produced by using magnetic fields such as horizontal magnetic field and cusp magnetic field, and by optimizing operation parameters as appropriate, such as crystal rotation rate, crucible rotation rate, magnetic field intensity, and excitation form.

In low-oxygen silicon single crystals, however, the dislocation locking effect by oxygen is weak and occurrence of slip is noticeable during a high-temperature and long-duration process (heat treatment). This reduces yields in fabrication of RF devices and power devices. One of methods for improving resistance against the slip is to add nitrogen into a silicon single crystal. Since nitrogen in a silicon single crystal has a higher dislocation locking ability than oxygen, a high concentration of nitrogen in a silicon single crystal can suppress occurrence of slip in a high-temperature and long-duration device process.

However, adding nitrogen into a silicon single crystal causes formation of nitrogen donors (NO donors). The nitrogen donors are annihilated by the high-temperature and long-duration process (heat treatment). The resistivity is therefore not changed after the process, but nitrogen donors remain in the as-grown crystal. In particular, in a high-resistivity crystal with resistivity of 100 Ωcm or higher, change in resistivity is noticeable due to the remaining nitrogen donors and causes a significant deviation from the intrinsic resistivity derived from a dopant is increased.

To solve this problem, for example, Patent Document 4 discloses a method in which a nitrogen-added silicon single crystal with resistivity of 1000 Ωcm or higher is fabricated by a floating zone (FZ) method; resistivity measurement sample (silicon single crystal substrate) is taken from the crystal; then heat treatment is performed at 900 to 1250° C. for 10 to 120 minutes; and then resistivity measurement is performed. According to Patent Document 4, the resistivity measurement sample is subjected to heat treatment under any one of a wet oxygen atmosphere, a dry oxygen atmosphere, and a nitrogen atmosphere, and the resistivity measurement is performed without treatment after the heat treatment.

### CITATION LIST

### Patent Literature

Patent Document 1: JP 2009-18984 A
Patent Document 2: WO 2009/025340 A1
Patent Document 3: JP 7124938 B
Patent Document 4: WO 2005/010243 A1
Patent Document 5: JP 2007-176725 A

### SUMMARY OF INVENTION

### Technical Problem

However, the heat treatment in an oxygen atmosphere forms a thermal oxide film on a sample surface, and if the resistivity measurement is performed with the thermal oxide film left on the sample surface, a precise resistivity derived from a dopant is unable to be obtained. Moreover, the heat treatment in a nitrogen atmosphere causes out-diffusion of nitrogen in the silicon single crystal and in-diffusion from the nitrogen atmosphere simultaneously, and nitrogen donors (NO donors) may remain in some heat treatment conditions.

Patent Document 5 discloses a method in which a nitrogen-added silicon single crystal with resistivity of 1000 Ωcm or higher is fabricated by the FZ method; resistivity measurement sample is taken from the crystal; then heat treatment and neutron radiation are performed; and then resistivity measurement is performed. In the technology of Patent Document 5, the resistivity measurement sample is subjected to heat treatment under a wet oxygen or dry oxygen atmosphere and then neutron radiation, and the resistivity measurement is performed after the neutron radiation. This technology also fails to obtain a precise resistivity derived from a dopant, because the resistivity measurement is performed with the thermal oxide film left on the sample surface.

The present invention is made in order to solve the above problem. An object of the present invention is to provide a method for measuring the resistivity of a silicon single crystal that can measure a precise resistivity derived from a dopant for a silicon single crystal with resistivity of 100 Ωcm or higher that is grown with addition of nitrogen by the MCZ method.

### Solution to Problem

To achieve the object, the present invention provides a method for measuring resistivity of a silicon single crystal with resistivity of 100 Ωcm or higher that is grown with addition of nitrogen by an MCZ method. The method includes: performing oxidation heat treatment at a temperature of 1100 to 1250° C. for 90 to 240 minutes on a substrate sliced from the silicon single crystal to form a thermal oxide film on a surface of the substrate; and measuring resistivity of the substrate after removing the thermal oxide film from the surface of the substrate.

With such a method for measuring resistivity of a silicon single crystal, first, oxidation heat treatment at a temperature of 1100 to 1250° C. for 90 to 240 minutes is performed on nitrogen donors formed in the silicon single crystal grown with addition of nitrogen, thereby annihilating the nitrogen donors and suppressing change in resistivity due to the remaining nitrogen donors. Next, the thermal oxide film formed on the substrate surface by the oxidation heat treatment is removed, thereby eliminating the effect of the remaining thermal oxide film on the resistivity. As a result, a precise resistivity derived from a dopant can be measured even for a nitrogen-added silicon single crystal with a high resistivity such as 100 Ωcm or higher.

In the method for measuring resistivity of a silicon single crystal according to the present invention, it is preferable that the surface of the substrate is ground after the thermal oxide film on the surface of the substrate is removed by etching with hydrofluoric acid.

Etching with hydrofluoric acid is easy and advantageous in terms of cost, and the subsequent grinding of the substrate surface ensures that the thermal oxide film is removed.

In the method for measuring resistivity of a silicon single crystal according to the present invention, it is preferable that the silicon single crystal has a nitrogen concentration of 3.0×10¹⁴ atoms/cm³ or more and an oxygen concentration of 8.0×10¹⁷ atoms/cm³ (ASTM′79) or less.

With such a method for measuring resistivity of a silicon single crystal, since the silicon single crystal has an oxygen concentration of 8.0×10¹⁷ atoms/cm³ (ASTM′79) or less, not only the oxygen donor concentration but also the nitrogen donor (NO donor) concentration can be suppressed, thereby enabling more accurate resistivity measurement. However, in low-oxygen silicon single crystals, the dislocation locking effect by oxygen is weak and occurrence of slip is noticeable during a high-temperature and long-duration process (heat treatment). This reduces yields in device fabrication. Then, the nitrogen concentration of the silicon single crystal is set to 3.0×10¹⁴ atoms/cm³ or more to impart slip resistance enough to withstand a high-temperature and long-duration process. As a result, accurate resistivity measurement can be implemented while preventing yield decrease during device fabrication.

### Advantageous Effects of Invention

The method for measuring resistivity of a silicon single crystal according to the present invention can precisely measure the resistivity of a silicon single crystal with resistivity of 100 Ωcm or higher that is grown with addition of nitrogen by the MCZ method. First, oxidation heat treatment at a temperature of 1100 to 1250° C. for 90 to 240 minutes is performed on nitrogen donors formed in the silicon single crystal grown with addition of nitrogen, thereby annihilating the nitrogen donors and suppressing change in resistivity due to the remaining nitrogen donors. Next, the thermal oxide film formed on the substrate surface by the oxidation heat treatment is removed, thereby eliminating the effect of the remaining thermal oxide film on the resistivity. As a result, a precise resistivity derived from a dopant can be measured even for a nitrogen-added silicon single crystal with a high resistivity such as 100 Ωcm or higher.

### BRIEF DESCRIPTION OF DRAWINGS

FIG. 1 is a flowchart illustrating a method for measuring resistivity of a silicon single crystal according to an embodiment of the present invention;

FIG. 2 is a diagram illustrating a pulling apparatus in an MCZ method under a horizontal magnetic field for use in the present invention; and

FIG. 3 is a diagram illustrating a pulling apparatus in an MCZ method under a cusp magnetic field for use in the present invention.

### DESCRIPTION OF EMBODIMENTS

Hereinafter, the present invention will be described in detail. However, the present invention is not limited thereto.

As described above, nitrogen donors remain in the as-grown nitrogen-added silicon single crystal. In particular, in a high-resistivity crystal with resistivity of 100 Ωcm or higher, change in resistivity is noticeable due to the remaining nitrogen donors and causes a significant deviation from the intrinsic resistivity derived from a dopant. As a solution to this problem, Patent Document 4 and Patent Document 5 disclose a method that measures the resistivity after heat treatment in an oxygen atmosphere or after heat treatment in an oxygen atmosphere and neutron radiation. However, the heat treatment at high temperature in an oxygen atmosphere forms a thermal oxide film on the silicon single crystal substrate surface, and with the thermal oxide film remaining, a precise resistivity derived from a dopant is unable to be obtained.

There has been a need for a method for measuring the resistivity of a silicon single crystal that can measure a precise resistivity derived from a dopant for a silicon single crystal with resistivity of 100 Ωcm or higher that is grown with addition of nitrogen by the MCZ method.

The inventors of the present invention have conducted elaborate studies on the above problem, and found that, first, change in resistivity due to the remaining nitrogen donors can be suppressed by performing oxidation heat treatment at a temperature of 1100 to 1250° C. for 90 to 240 minutes on nitrogen donors formed in a silicon single crystal grown with addition of nitrogen to form a thermal oxide film on a substrate surface and annihilate the nitrogen donors. It has been found that, next, the effect of the remaining thermal oxide film on the resistivity can be eliminated by removing the thermal oxide film formed on the substrate surface by the oxidation heat treatment. As a result, the inventors have found a method for measuring a precise resistivity derived from a dopant even for a nitrogen-added silicon single crystal with a high resistivity such as 100 Ωcm or higher. This finding has led to completion of the present invention.

Specifically, the present invention provides a method for measuring resistivity of a silicon single crystal with resistivity of 100 Ωcm or higher that is grown with addition of nitrogen by an MCZ method. The method includes: performing oxidation heat treatment at a temperature of 1100 to 1250° C. for 90 to 240 minutes on a substrate sliced from the silicon single crystal to form a thermal oxide film on a surface of the substrate; and measuring resistivity of the substrate after removing the thermal oxide film from the surface of the substrate.

Embodiments of the present invention will be described in detail below with reference to the drawings.

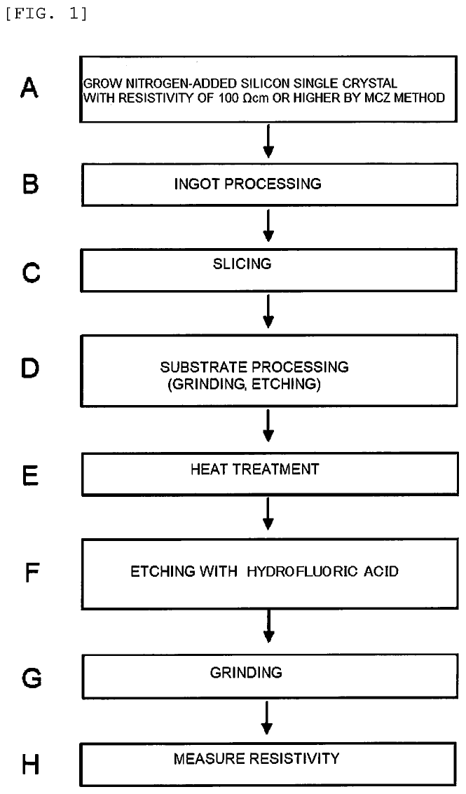

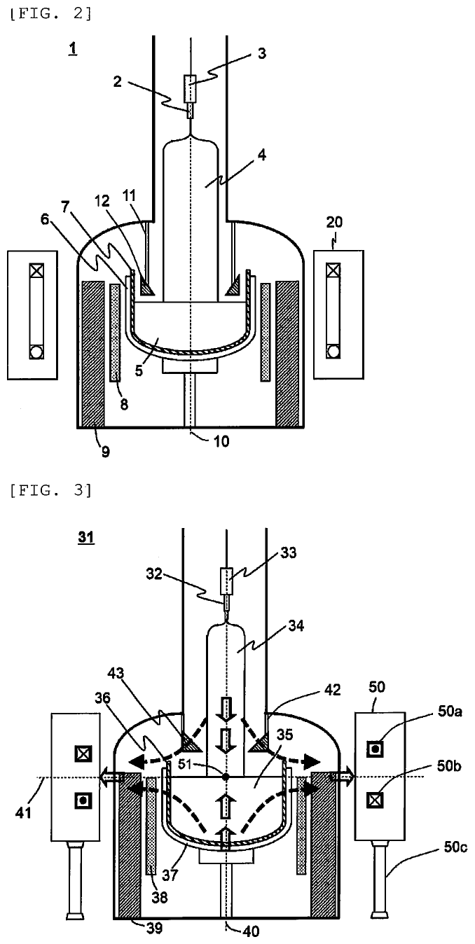

First, referring to FIG. 1, FIG. 2, and FIG. 3, an exemplary method for measuring the resistivity of a silicon single crystal according to an embodiment of the present invention will be described.

In the present invention, a nitrogen-added silicon single crystal with resistivity of 100 Ωcm or higher is grown by the magnetic field applied CZ method (MCZ method), but the magnetic field is not limited to a particular form and may be a horizontal magnetic field or a cusp magnetic field.

As illustrated in FIG. 2, a single crystal producing apparatus with a horizontal magnetic field includes a silicon single crystal pulling apparatus (pulling furnace) 1 having a central axis 10 with a heater 8 and a heat shielding member 12 facing a raw material melt (silicon melt) 5 stored in a quartz crucible 7, and a horizontal magnetic field generator 20 surrounding the pulling furnace 1. A superconducting coil inside the horizontal magnetic field generator 20 is energized to apply a horizontal magnetic field to the silicon melt 5, and a silicon single crystal 4 is pulled up in a direction of the central axis 10. The silicon single crystal pulling apparatus 1 further includes a seed crystal 2, a seed holder 3, a graphite crucible 6, a heat insulating member 9, and a cylindrical part 11.

As illustrated in FIG. 3, a single crystal producing apparatus with a cusp magnetic field includes a silicon single crystal pulling apparatus (pulling furnace) 31 having a central axis 40 with a heater 38 and a heat shielding member 43 facing a raw material melt (silicon melt) 35 stored in a quartz crucible 36, and a cusp magnetic field generator 50 surrounding the pulling furnace 31 and having an upper coil (superconducting coil) 50a and a lower coil (superconducting coil) 50b. The superconducting coils 50a and 50b are energized to apply a cusp magnetic field to the silicon melt 35, and a silicon single crystal 34 is pulled up in a direction of the central axis 40. The silicon single crystal pulling apparatus 31 further includes a seed crystal 32, a seed holder 33, a graphite crucible 37, a heat insulating member 39, and a cylindrical part 42.

The cusp magnetic field generator 50 is installed on an elevator 50c movable upward and downward vertically. The upper coil 50a and the lower coil 50b are disposed so as to surround a side surface of the silicon single crystal pulling apparatus 31. In a cusp magnetic field, currents in opposite directions are fed to the upper and lower coils to generate magnetic lines of flux repulsing vertically. A magnetic field distribution symmetric vertically and symmetric front to back and left to right can be formed by setting the same current value for the upper coil 50a and the lower coil 50b and feeding currents in opposite directions to the upper and lower coils. In this case, a magnetic field minimum point 51 at an intersection of the central axis 40 and an intermediate plane 41 between the two coils has a magnetic field intensity of 0 G (Gauss). For example, the magnetic field minimum point position of the cusp magnetic field is set 10 mm below the raw material melt surface, and the magnetic field intensity at the intersection of the intermediate plane 41 between the upper and lower coils and the crucible wall is 1000 G, whereby a silicon single crystal with an oxygen concentration of 8.0×10¹⁷ atoms/cm³ (ASTM′79) or less can be easily produced. The nitrogen concentration of the silicon single crystal is preferably 3.0×10¹⁴ atoms/cm³ or more.

With such a silicon single crystal, since the silicon single crystal has an oxygen concentration of 8.0×10¹⁷ atoms/cm³ (ASTM′79) or less, not only the oxygen donor concentration but also the nitrogen donor (NO donor) concentration can be suppressed, thereby enabling more accurate resistivity measurement. However, in low-oxygen silicon single crystals, the dislocation locking effect by oxygen is weak and occurrence of slip is noticeable during a high-temperature and long-duration process (heat treatment). This reduces yields in device fabrication. Then, the nitrogen concentration of the silicon single crystal is set to 3.0×10¹⁴ atoms/cm³ or more to impart slip resistance enough to withstand a high-temperature and long-duration process. As a result, accurate resistivity measurement can be implemented while preventing yield decrease during device fabrication.

As described above, a nitrogen-added silicon single crystal with resistivity of 100 Ωcm or higher can be grown, for example, by the MCZ method using a silicon single crystal pulling apparatus with a horizontal magnetic field or a cusp magnetic field.

FIG. 1 is a flowchart illustrating a method for measuring the resistivity of a silicon single crystal. Specific steps are denoted by A to H. After the growth of the nitrogen-added silicon single crystal with resistivity of 100 Ωcm or higher described above (step A) is completed, ingot processing (outer diameter grinding) is performed on the silicon single crystal (step B), and then the silicon single crystal is sliced using an inner diameter slicer or a wire saw (step C) into a silicon single crystal substrate with a predetermined thickness. After grinding and acid etching of a substrate surface (step D) is completed, oxidation heat treatment for removing nitrogen donors (step E) is performed. The atmosphere in the oxidation heat treatment may be a wet oxygen atmosphere or a dry oxygen atmosphere. In a dry oxygen atmosphere or a wet oxygen atmosphere, the temperature during heat treatment is set to 1100 to 1250° C., and heat treatment is performed with this temperature kept for 90 to 240 minutes. Such oxidation heat treatment can annihilate nitrogen donors and suppress change in resistivity due to the remaining nitrogen donors.

If the treatment time of the above heat treatment is shorter than 90 minutes, the nitrogen donors remain. If the treatment time of the above heat treatment is longer than 240 minutes, for example, 250 minutes or longer, the nitrogen donors are completely eliminated but the longer treatment time significantly reduces the heater life of the heat treatment furnace and reduces the throughput of resistivity measurement. For those reasons, the treatment time of the heat treatment is 90 to 240 minutes. The heat treatment furnace used for heat treatment for removing nitrogen donors may be a horizontal furnace or a vertical furnace.

After the heat treatment for removing nitrogen donors (step E) is completed, the thermal oxide film is removed from the substrate surface. The removal of the thermal oxide film can eliminate the effect of the remaining thermal oxide film on the resistivity. As a result, a precise resistivity derived from a dopant can be measured even for a nitrogen-added silicon single crystal with a high resistivity such as 100 Ωcm or higher.

In this case, for example, etching with hydrofluoric acid can be performed (step F). Etching with hydrofluoric acid is easy and advantageous in terms of cost. In this case, if the hydrofluoric acid concentration is 0.1 wt % or more, the thermal oxide film attributable to the heat treatment can be removed with no problem.

After the oxide film removal (step F) is completed, it is preferable to further perform grinding on the substrate surface (step G). The grinding of the substrate surface ensures that the thermal oxide film is removed. In this case, it is preferable that the grinding is performed using a grindstone or a grinding pad, and the grinding removal is 5 μm or more. Further, the size of abrasive grains used in the grinding in this case may be about #300 for coarse grinding or may be about #2000 for fine grinding.

In this way, when etching with hydrofluoric acid and grinding are performed as a method for removing the thermal oxide film, the etching with hydrofluoric acid is easy and advantageous in terms of cost, and the subsequent grinding of the substrate surface ensures that the thermal oxide film is removed.

Thereafter, resistivity measurement is performed (step H). The measurement can be performed by a method such as four-point probes method, spreading resistance method, and Hall effect method.

By using the conditions described above, it is possible to precisely perform resistivity measurement of a nitrogen-added silicon single crystal with a high resistivity such as 100 Ωcm or higher that is grown by the MCZ method.

### EXAMPLES

In a quartz crucible with a diameter of 800 mm, 360 kg of a silicon raw material was charged and melted, and a cusp magnetic field was applied. A 300 mm-diameter nitrogen-added silicon single crystal with a target P-type resistivity of 2000 Ωcm (boron dopant) was pulled up by using each of four different pulling apparatuses, resulting in a total of four silicon single crystals. The pulled-up silicon single crystal was subjected to ingot processing to produce a silicon single crystal substrate. The produced silicon single crystal substrate was subjected to heat treatment in an oxygen atmosphere, and after the heat treatment, a thermal oxide film on the substrate surface was removed by hydrofluoric acid etching. After removing the thermal oxide film, the silicon substrate was ground using a grindstone with a grain size #2000, and measurement of resistivity was performed for the silicon substrate by the four-point probes method. In Examples and Comparative Examples, the ratio of the measured value of resistivity to the resistivity_calculated from the amount of dopant (segregation curve) is defined as “(resistivity_measured value)/(resistivity_calculated value)”. When the ratio is less than 1.05 (the increase is less than 5%), the resistivity derived from a dopant (boron) is considered to be obtained, and the resistivity is considered to be measurable (evaluation is good), and otherwise the resistivity is considered to be not measurable (evaluation is poor).

### Example 1

In Example 1, a silicon single crystal substrate was prepared from a portion with a nitrogen concentration of 3.0×10¹⁵ atoms/cm³ and an oxygen concentration of 1.5×10¹⁷ atoms/cm³ (ASTM′79) in the silicon single crystal, and heat treatment was performed on the single crystal substrate in a wet oxygen atmosphere. In total, four combinations of temperature and time were employed in the heat treatment: temperature 1100° c.×time 90 minutes, temperature 1100° c.×time 240 minutes, temperature 1250° c.×time 90 minutes, and temperature 1250° c.×time 240 minutes. After the heat treatment, the thermal oxide film on the substrate surface was removed by hydrofluoric acid etching and ground using a grindstone with a grain size #2000, and measurement of resistivity was performed by the four-point probes method. As a result, the (resistivity_measured value)/(resistivity_calculated value) was 1.00 in all cases, indicating that the dopant (boron)-derived resistivity was obtained extremely precisely because of annihilation of nitrogen donors. Table 1 shows the ratio of (resistivity_measured value) to (resistivity_calculated value) and whether resistivity is measurable in the resistivity measurement performed under the conditions of Example 1.

TABLE 1

| | | Heat | Heat | (Resistivity_{—} | |
|---|---|---|---|---|---|
| Nitrogen | Oxygen | treatment | treatment | measured value)/ | |
| concentration | concentration | temperature | time | (resistivity_{—} | Resistivity |
| [atoms/cm³] | [atoms/cm³] | [° C.] | [min] | calculated value) [—] | measurability |
| 3.0 × 10¹⁵ | 1.5 × 10¹⁷ | 1100 | 90 | 1.00 | Good |
| 3.0 × 10¹⁵ | 1.5 × 10¹⁷ | 1100 | 240 | 1.00 | Good |
| 3.0 × 10¹⁵ | 1.5 × 10¹⁷ | 1250 | 90 | 1.00 | Good |
| 3.0 × 10¹⁵ | 1.5 × 10¹⁷ | 1250 | 240 | 1.00 | Good |

Besides Example 1, measurement of resistivity was performed in which heat treatment for nitrogen donors annihilation was in a dry oxygen atmosphere and other conditions were the same as in Example 1. As a result, the (resistivity_measured value)/(resistivity_calculated value) was 1.00 in all cases, indicating that the dopant (boron)-derived resistivity was obtained extremely precisely. In addition, besides Example 1, measurement of resistivity was performed in which the resistivity in the single crystal was 100 Ωcm and other conditions were the same as in Example 1. As a result, it was confirmed that the dopant (boron)-derived resistivity was obtained in all cases.

### Example 2

In Example 2, measurement of resistivity was performed in which the oxygen concentration in the silicon single crystal was 8.0×10¹⁷ atoms/cm³ (ASTM′79) and other conditions were the same as in Example 1. As a result, the (resistivity_measured value)/(resistivity_calculated value) was 1.01 or less in all cases, indicating that the dopant (boron)-derived resistivity was obtained precisely because of annihilation of nitrogen donors. Table 2 shows the ratio of (resistivity_measured value) to (resistivity_calculated value) and whether resistivity is measurable in the resistivity measurement performed under the conditions of Example 2.

TABLE 2

| | | Heat | Heat | (Resistivity_{—} | |
|---|---|---|---|---|---|
| Nitrogen | Oxygen | treatment | treatment | measured value)/ | |
| concentration | concentration | temperature | time | (resistivity_{—} | Resistivity |
| [atoms/cm³] | [atoms/cm³] | [° C.] | [min] | calculated value) [—] | measurability |
| 3.0 × 10¹⁵ | 8.0 × 10¹⁷ | 1100 | 90 | 1.01 | Good |
| 3.0 × 10¹⁵ | 8.0 × 10¹⁷ | 1100 | 240 | 1.01 | Good |
| 3.0 × 10¹⁵ | 8.0 × 10¹⁷ | 1250 | 90 | 1.00 | Good |
| 3.0 × 10¹⁵ | 8.0 × 10¹⁷ | 1250 | 240 | 1.00 | Good |

Besides Example 2, measurement of resistivity was performed in which heat treatment for nitrogen donors annihilation was in a dry oxygen atmosphere and other conditions were the same as in Example 2. As a result, the (resistivity_measured value)/(resistivity_calculated value) was 1.01 or less in all cases, indicating that the dopant (boron)-derived resistivity was obtained precisely. In addition, besides Example 2, measurement of resistivity was performed in which the resistivity in the single crystal was 100 Ωcm and other conditions were the same as in Example 2. As a result, it was confirmed that the dopant (boron)-derived resistivity was obtained in all cases.

### Example 3

In Example 3, measurement of resistivity was performed in which the nitrogen concentration in the silicon single crystal was 3.0×10¹⁴ atoms/cm³ and other conditions were the same as in Example 1. As a result, the (resistivity_measured value)/(resistivity_calculated value) was 1.00 in all cases, indicating that the dopant (boron)-derived resistivity was obtained extremely precisely because of annihilation of nitrogen donors. Table 3 shows the ratio of (resistivity_measured value) to (resistivity_calculated value) and whether resistivity is measurable in the resistivity measurement performed under the conditions of Example 3.

TABLE 3

| | | Heat | Heat | (Resistivity_{—} | |
|---|---|---|---|---|---|
| Nitrogen | Oxygen | treatment | treatment | measured value)/ | |
| concentration | concentration | temperature | time | (resistivity_{—} | Resistivity |
| [atoms/cm³] | [atoms/cm³] | [° C.] | [min] | calculated value) [—] | measurability |
| 3.0 × 10¹⁴ | 1.5 × 10¹⁷ | 1100 | 90 | 1.00 | Good |
| 3.0 × 10¹⁴ | 1.5 × 10¹⁷ | 1100 | 240 | 1.00 | Good |
| 3.0 × 10¹⁴ | 1.5 × 10¹⁷ | 1250 | 90 | 1.00 | Good |
| 3.0 × 10¹⁴ | 1.5 × 10¹⁷ | 1250 | 240 | 1.00 | Good |

Besides Example 3, measurement of resistivity was performed in which heat treatment for nitrogen donors annihilation was in a dry oxygen atmosphere and other conditions were the same as in Example 3. As a result, the (resistivity_measured value)/(resistivity_calculated value) was 1.00 in all cases, indicating that the dopant (boron)-derived resistivity was obtained extremely precisely. In addition, besides Example 3, measurement of resistivity was performed in which the resistivity in the single crystal was 100 Ωcm and other conditions were the same as in Example 3. As a result, it was confirmed that the dopant (boron)-derived resistivity was obtained in all cases.

### Example 4

In Example 4, measurement of resistivity was performed in which the oxygen concentration in the silicon single crystal was 9.0×10¹⁷ atoms/cm³ (ASTM′79) and other conditions were the same as in Example 1. As a result, the (resistivity_measured value)/(resistivity_calculated value) was 1.03 to 1.04 and a dopant (boron)-derived resistivity was obtained. Comparing this result with the results of Examples 1 and 2 indicates that more precise measurement can be performed in Examples 1 and 2. Therefore, it can be said that the oxygen concentration is more preferably 8.0×10¹⁷ atoms/cm³ (ASTM′79) or less as in Example 2, because if so, the ratio can be 1.01 or less. Table 4 shows the ratio of (resistivity_measured value) to (resistivity_calculated value) and whether resistivity is measurable in the resistivity measurement performed under the conditions of Example 4.

TABLE 4

| | | Heat | Heat | (Resistivity_{—} | |
|---|---|---|---|---|---|
| Nitrogen | Oxygen | treatment | treatment | measured value)/ | |
| concentration | concentration | temperature | time | (resistivity_{—} | Resistivity |
| [atoms/cm³] | [atoms/cm³] | [° C.] | [min] | calculated value) [—] | measurability |
| 3.0 × 10¹⁵ | 9.0 × 10¹⁷ | 1100 | 90 | 1.04 | Good |
| 3.0 × 10¹⁵ | 9.0 × 10¹⁷ | 1100 | 240 | 1.04 | Good |
| 3.0 × 10¹⁵ | 9.0 × 10¹⁷ | 1250 | 90 | 1.04 | Good |
| 3.0 × 10¹⁵ | 9.0 × 10¹⁷ | 1250 | 240 | 1.03 | Good |

### Comparative Example 1

In Comparative Example 1, measurement of resistivity was performed with in total four combinations of temperature and time in the heat treatment: temperature 900° c.×time 90 minutes, temperature 900° c.×time 240 minutes, temperature 1000° c.×time 90 minutes, temperature 1000° c.×time 240 minutes, and other conditions were the same as in Example 1. As a result, the (resistivity_measured value)/(resistivity_calculated value) was 1.82 to 3.40, and nitrogen donors remained even after heat treatment, causing change in resistivity. As a result, a precise resistivity derived from a dopant (boron) was not obtained. Table 5 shows the ratio of (resistivity_measured value) to (resistivity_calculated value) and whether resistivity is measurable in the resistivity measurement performed under the conditions of Comparative Example 1.

TABLE 5

| | | Heat | Heat | (Resistivity_{—} | |
|---|---|---|---|---|---|
| Nitrogen | Oxygen | treatment | treatment | measured value)/ | |
| concentration | concentration | temperature | time | (resistivity_{—} | Resistivity |
| [atoms/cm³] | [atoms/cm³] | [° C.] | [min] | calculated value) [—] | measurability |
| 3.0 × 10¹⁵ | 1.5 × 10¹⁷ | 900 | 90 | 3.40 | Poor |
| 3.0 × 10¹⁵ | 1.5 × 10¹⁷ | 900 | 240 | 3.00 | Poor |
| 3.0 × 10¹⁵ | 1.5 × 10¹⁷ | 1000 | 90 | 2.47 | Poor |
| 3.0 × 10¹⁵ | 1.5 × 10¹⁷ | 1000 | 240 | 1.82 | Poor |

Besides Comparative Example 1, measurement of resistivity was performed in which the temperature and time in heat treatment was changed to temperature 1000° c.×time 480 minutes and other conditions were the same as in Comparative Example 1. As a result, the (resistivity_measured value)/(resistivity_calculated value) was 1.50 and a precise resistivity derived from a dopant (boron) was not obtained.

### Comparative Example 2

In Comparative Example 2, measurement of resistivity was performed with in total four combinations of temperature and time in the heat treatment: temperature 1100° c.×time 30 minutes, temperature 1100° c.×time 60 minutes, temperature 1250° c.×time 30 minutes, and temperature 1250° c.×time 60 minutes, and other conditions were the same as in Example 1. As a result, the (resistivity_measured value)/(resistivity_calculated value) was 1.05 to 1.45, and nitrogen donors remained even after heat treatment, causing change in resistivity. As a result, a precise resistivity derived from a dopant (boron) was not obtained. Table 6 shows the ratio of (resistivity_measured value) to (resistivity_calculated value) and whether resistivity is measurable in the resistivity measurement performed under the conditions of Comparative Example 2.

TABLE 6

| | | Heat | Heat | (Resistivity_{—} | |
|---|---|---|---|---|---|
| Nitrogen | Oxygen | treatment | treatment | measured value)/ | |
| concentration | concentration | temperature | time | (resistivity_{—} | Resistivity |
| [atoms/cm³] | [atoms/cm³] | [° C.] | [min] | calculated value) [—] | measurability |
| 3.0 × 10¹⁵ | 1.5 × 10¹⁷ | 1100 | 30 | 1.45 | Poor |
| 3.0 × 10¹⁵ | 1.5 × 10¹⁷ | 1100 | 60 | 1.21 | Poor |
| 3.0 × 10¹⁵ | 1.5 × 10¹⁷ | 1250 | 30 | 1.10 | Poor |
| 3.0 × 10¹⁵ | 1.5 × 10¹⁷ | 1250 | 60 | 1.05 | Poor |

As described above, in Examples according to the present invention, nitrogen donors were annihilated by performing oxidation heat treatment at a temperature of 1100 to 1250° C. for 90 to 240 minutes on a silicon single crystal with resistivity of 100 Ωcm or higher that was grown with addition of nitrogen by the MCZ method, whereby change in resistivity due to the remaining nitrogen donors can be suppressed. The effect of the remaining thermal oxide film on the resistivity was eliminated by removing the thermal oxide film formed on the substrate surface by the oxidation heat treatment. As a result, a precise resistivity derived from a dopant was able to be measured even for a nitrogen-added silicon single crystal with a high resistivity such as 100 Ωcm or higher.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A method for measuring resistivity of a silicon single crystal with resistivity of 100 Ωcm or higher, the silicon single crystal being grown with addition of nitrogen by an MCZ method, the method comprising: performing oxidation heat treatment at a temperature of 1100 to 1250° C. for 90 to 240 minutes on a substrate sliced from the silicon single crystal to form a thermal oxide film on a surface of the substrate; and measuring resistivity of the substrate after removing the thermal oxide film from the surface of the substrate.

2. The method for measuring resistivity of a silicon single crystal according to claim 1, wherein the surface of the substrate is ground after the thermal oxide film on the surface of the substrate is removed by etching with hydrofluoric acid.

3. The method for measuring resistivity of a silicon single crystal according to claim 1, wherein the silicon single crystal has a nitrogen concentration of 3.0×10¹⁴ atoms/cm³ or more and an oxygen concentration of 8.0×10¹⁷ atoms/cm³ (ASTM′79) or less.

4. The method for measuring resistivity of a silicon single crystal according to claim 2, wherein the silicon single crystal has a nitrogen concentration of 3.0×10¹⁴ atoms/cm³ or more and an oxygen concentration of 8.0×10¹⁷ atoms/cm³ (ASTM′79) or less.
